(19) United States
(12) Patent Application Publication
(10) Pub. No.: US 2025/0372956 A1
(43) Pub. Date: Dec. 4, 2025

(54) SILICON PHOTONIC PLATFORM

(71) Applicant: International Business Machines Corporation, Armonk, NY (US)

(72) Inventors: Neng Liu, Albany, NY (US); Hsianghan Hsu, Latham, NY (US); Qianwen Chen, Chappaqua, NY (US); John Knickerbocker, Monroe, NY (US)

(21) Appl. No.: 18/732,782

(22) Filed: Jun. 4, 2024

(51) Int. Cl. H01S 5/343; H01S 5/02; H01S 5/026; H01S 5/042

(52) U.S. Cl. CPC H01S 5/343; H01S 5/021; H01S 5/0215; H01S 5/026; H01S 5/0421

(57) ABSTRACT

A photonic device is provided and includes a waveguide, a p-n junction disposed on the waveguide, a first contact and a second contact. The p-n junction includes a quantum well between an upper portion doped with a first dopant and a lower portion doped with a second dopant. The first contact is doped with the first dopant and is disposed in contact with the upper portion. The second contact is doped with the second dopant and includes a first lead and a second lead. The first lead extends through a first side of the waveguide and terminates at a corresponding first side of the lower portion. The second lead extends through a second side of the waveguide and terminates at a corresponding second side of the lower portion.

### BACKGROUND

The present disclosure generally relates to fabrication methods and resulting structures for silicon photonic platforms. More specifically, the present disclosure relates to a high electrical pump efficiency III-V laser for a heterogenous integrated silicon photonic platform.

Silicon photonics is the study and application of photonic systems using silicon as an optical medium. The silicon is patterned into micro-photonic components that operate in infrared. Silicon photonic devices can be made using existing semiconductor fabrication techniques, and because silicon is already used as the substrate for most integrated circuits, it is possible to create hybrid devices in which the optical and electronic components are integrated onto a single microchip. The propagation of light through silicon photonic devices is governed by a range of nonlinear optical phenomena including the Kerr effect, the Raman effect, two-photon absorption and interactions between photons and free charge carriers.

### SUMMARY

According to an aspect of the disclosure, a photonic device is provided and includes a waveguide, a p-n junction disposed on the waveguide, a first contact and a second contact. The p-n junction includes a quantum well between an upper portion doped with a first dopant and a lower portion doped with a second dopant. The first contact is doped with the first dopant and is disposed in contact with the upper portion. The second contact is doped with the second dopant and includes a first lead and a second lead. The first lead extends through a first side of the waveguide and terminates at a corresponding first side of the lower portion. The second lead extends through a second side of the waveguide and terminates at a corresponding second side of the lower portion. In one or more additional or alternative embodiments, the photonic device exhibits size by reducing electrical path resistance from metallic contacts to a III-V gain region.

According to an aspect of the disclosure, a silicon photonic device is provided and includes a semiconductor substrate, a silicon channel embedded in the semiconductor substrate, a p-n junction disposed on the semiconductor substrate, a first contact and a second contact. The p-n junction includes a quantum well between an upper portion doped with a first dopant and a lower portion doped with a second dopant. The first contact is doped with the first dopant and is disposed in contact with the upper portion. The second contact is doped with the second dopant and includes a first lead and a second lead. The first lead extends through a first side of the semiconductor substrate and terminates at a corresponding first side of the lower portion. The second lead extends through a second side of the semiconductor substrate and terminates at a corresponding second side of the lower portion. In one or more additional or alternative embodiments, the photonic device exhibits relatively high electrical pump efficiency with improved optical confinement and reduced size by reducing electrical path resistance from metallic contacts to a III-V gain region.

According to an aspect of the disclosure, a method of assembling a photonic device is provided and includes fabricating a waveguide and fabricating a lower contact doped with a lower contact dopant. The fabricating of the lower contact includes forming a first lead extending through and terminating at a first side of the waveguide and forming a second lead extending through and terminating at a second side of the waveguide. The method further includes bonding, onto the waveguide, a p-n junction including a quantum well between an upper portion doped with an upper contact dopant and a lower portion doped with the lower contact dopant. The bonding is executed such that the lower portion contacts the first and second leads. The method also includes patterning the waveguide and fabricating an upper contact doped with the upper contact dopant to contact the upper portion. In one or more additional or alternative embodiments, the method results in the fabrication of a photonic device that exhibits size by a reduction of electrical path resistance from metallic contacts to a III-V gain region.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a plan view of a photonic device in accordance with one or more embodiments;

FIG. 2 is a graphical illustrating of an optical beam confined by the photonic device of FIG. 1 in accordance with one or more embodiments;

FIG. 3 is a flow diagram illustrating a method of assembling a photonic device in accordance with one or more embodiments; and

FIG. 4 is a graphical flow diagram illustrating the method of FIG. 3 in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a photonic device is provided and includes a waveguide, a p-n junction disposed on the waveguide, a first contact and a second contact. The p-n junction includes a quantum well between an upper portion doped with a first dopant and a lower portion doped with a second dopant. The first contact is doped with the first dopant and is disposed in contact with the upper portion. The second contact is doped with the second dopant and includes a first lead and a second lead. The first lead extends through a first side of the waveguide and terminates at a corresponding first side of the lower portion. The second lead extends through a second side of the waveguide and terminates at a corresponding second side of the lower portion. In one or more additional or alternative embodiments, the photonic device exhibits relatively high electrical pump efficiency with improved optical confinement and reduced size by reducing electrical path resistance from metallic contacts to a III-V gain region.

The waveguide is a silicon waveguide that provides a III-V platform for the photonic device.

The silicon waveguide includes a semiconductor substrate and a silicon channel embedded in the semiconductor substrate for optical coupling with the waveguide.

The upper portion includes a III-V semiconductor and the lower portion includes a III-V semiconductor. The III-V semiconductor provides for energy saving and provides a platform for thermally-controllable large-scale electronic-photonic integrated circuits (ICs).

The first contact is disposed around and over waveguide and includes a first contact lead contacting an upper surface of the upper portion. This configuration is compatible with lithographic techniques.

The first lead includes a first horizontal section that extends horizontally through the first side of the waveguide and a first vertical section that extends vertically from an end of the first horizontal section to a lowermost surface of the lower portion at the first side of the lower portion and the second lead includes a second horizontal section that extends horizontally through the second side of the waveguide and a second vertical section that extends vertically from an end of the second horizontal section to the lowermost surface of the lower portion at the second side of the lower portion. This configuration provides for a shorter contact and less electrical resistance.

The first dopant is a p-type dopant and the second dopant is an n-type dopant in multiple possible embodiments.

The first dopant is an n-type dopant and the second dopant is a p-type dopant in multiple possible embodiments.

According to an aspect of the disclosure, a silicon photonic device is provided and includes a semiconductor substrate, a silicon channel embedded in the semiconductor substrate, a p-n junction disposed on the semiconductor substrate, a first contact and a second contact. The p-n junction includes a quantum well between an upper portion doped with a first dopant and a lower portion doped with a second dopant. The first contact is doped with the first dopant and is disposed in contact with the upper portion. The second contact is doped with the second dopant and includes a first lead and a second lead. The first lead extends through a first side of the semiconductor substrate and terminates at a corresponding first side of the lower portion. The second lead extends through a second side of the semiconductor substrate and terminates at a corresponding second side of the lower portion. In one or more additional or alternative embodiments, the photonic device exhibits relatively high electrical pump efficiency with improved optical confinement and reduced size by reducing electrical path resistance from metallic contacts to a III-V gain region.

The upper portion includes a III-V semiconductor and the lower portion includes a III-V semiconductor. The III-V semiconductor provides for energy saving and provides a platform for thermally-controllable large-scale electronic-photonic integrated circuits (ICs).

The first contact is disposed around and over the semiconductor substrate and includes a first contact lead contacting an upper surface of the upper portion, the first lead includes a first horizontal section that extends horizontally through the first side of the semiconductor substrate and a first vertical section that extends vertically from an end of the first horizontal section to a lowermost surface of the lower portion at the first side of the lower portion and the second lead includes a second horizontal section that extends horizontally through the second side of the semiconductor substrate and a second vertical section that extends vertically from an end of the second horizontal section to the lowermost surface of the lower portion at the second side of the lower portion. This configuration provides for a shorter contact and less electrical resistance.

The first dopant is a p-type dopant and the second dopant is an n-type dopant in multiple possible embodiments.

The first dopant is an n-type dopant and the second dopant is a p-type dopant in multiple possible embodiments.

According to an aspect of the disclosure, a method of assembling a photonic device is provided and includes fabricating a waveguide and fabricating a lower contact doped with a lower contact dopant. The fabricating of the lower contact includes forming a first lead extending through and terminating at a first side of the waveguide and forming a second lead extending through and terminating at a second side of the waveguide. The method further includes bonding, onto the waveguide, a p-n junction including a quantum well between an upper portion doped with an upper contact dopant and a lower portion doped with the lower contact dopant. The bonding is executed such that the lower portion contacts the first and second leads. The method also includes patterning the waveguide and fabricating an upper contact doped with the upper contact dopant to contact the upper portion. In one or more additional or alternative embodiments, the method results in the fabrication of a photonic device that exhibits relatively high electrical pump efficiency with improved optical confinement and reduced size by a reduction of electrical path resistance from metallic contacts to a III-V gain region.

The waveguide includes a silicon waveguide and the fabricating of the waveguide includes fabricating a semiconductor substrate and embedding a silicon channel in the semiconductor substrate for optical coupling with the waveguide.

The forming of the first lead includes forming a first horizontal section that extends horizontally through the first side of the waveguide and forming a first vertical section that extends vertically from an end of the first horizontal section and the forming of the second lead includes forming a second horizontal section that extends horizontally through the second side of the waveguide and forming a second vertical section that extends vertically from an end of the second horizontal section. This provides for a shorter contact and less electrical resistance.

The upper portion includes a III-V semiconductor and the lower portion includes a III-V semiconductor. The III-V semiconductor provides for energy saving and provides a platform for thermally-controllable large-scale electronic-photonic integrated circuits (ICs).

The fabricating of the upper contact includes disposing the upper contact around and over the waveguide and forming an upper contact lead to contact an upper surface of the upper portion. This configuration is compatible with lithographic techniques.

The lower contact dopant is an n-type dopant and the upper contact dopant is a p-type dopant in multiple possible embodiments.

The lower contact dopant is a p-type dopant and the upper contact dopant is an n-type dopant in multiple possible embodiments.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, III-V heterogeneous integration on silicon (III-V-HI-Si) has been recently demonstrated to be a promising method for an on-chip light source for silicon photonics platforms. It has been found in many cases, however, that electrical pump efficiency on the III-V-HI-Si platform is lacking and that this leads to energy loss and uncontrolled thermal gradients. One cause of this is that, in typical configurations, one of the doped contacts tended to be formed as a long contact with correspondingly increased electrical resistance that, in turn, led to a lack of optical confinement in the beam.

Turning now to an overview of the aspects of the disclosure, one or more embodiments of the disclosure address the above-described shortcomings of the prior art by providing improved electrical pump efficiency on an III-V-HI-Si platform that offers energy savings and which is thermally controllable in large-scale electronic-photonic integrated circuits (ICs). The advantages are provided by a channel III-V waveguide, which has a metallic contact that is directly connected at a bottom of a III-V PN junction and thus reduced electrical resistance with improved optical confinement in the beam and increased electrical pump efficiency.

The above-described aspects of the disclosure address the shortcomings of the prior art by providing a photonic device, such as a silicon photonic device, that includes a waveguide, a p-n junction disposed on the waveguide and first and second contacts. The p-n junction includes a quantum well between an upper portion doped with a first dopant and a lower portion doped with a second dopant. The first contact is doped with the first dopant and is disposed in contact with the upper portion. The second contact is doped with the second dopant and includes first and second leads. The first lead extends through a first side of the waveguide and terminates at a corresponding first side of the lower portion. The second lead extends through a second side of the waveguide and terminates at a corresponding second side of the lower portion.

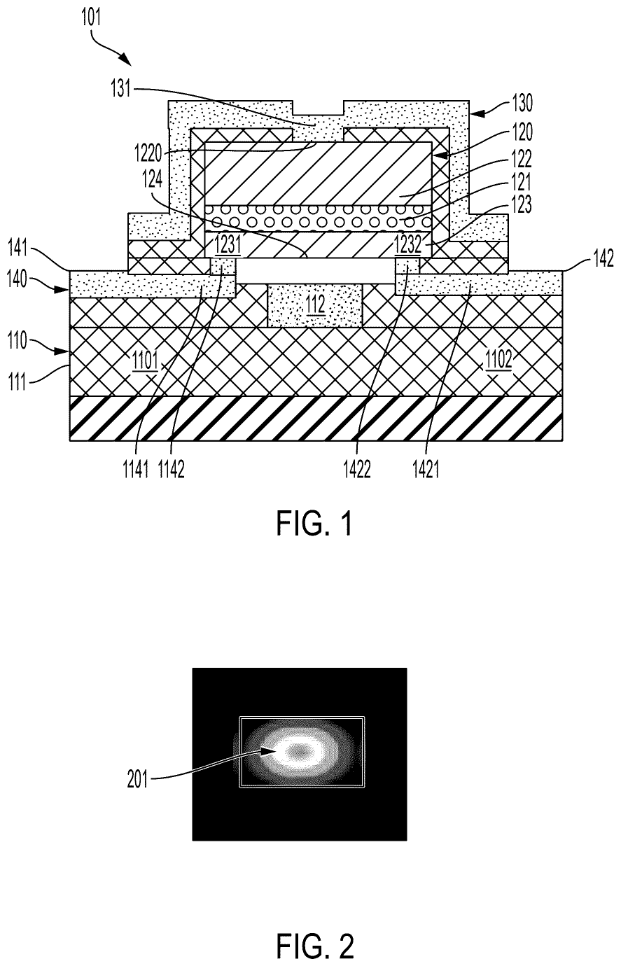

Turning now to a more detailed description of aspects of the present disclosure, FIG. 1 is a side view of a photonic device 101, such as a silicon photonic device. The photonic device 101 includes a waveguide 110, a p-n junction 120 disposed on the waveguide 110, a first contact 130 and a second contact 140. The waveguide 110 can be provided as a silicon waveguide and includes a semiconductor substrate 111 and a silicon channel 112 that is embedded in the semiconductor substrate 111. The p-n junction 120 is disposed on waveguide 110 and above the silicon channel 112 and includes a quantum well 121, an upper portion 122 and a lower portion 123. The quantum well 121 is vertically interposed between the upper portion 122 and the lower portion 123. The upper portion 122 includes a III-V semiconductor material and is doped with a first dopant. The lower portion 123 includes a III-V semiconductor material and is doped with a second dopant, which differs from the first dopant. An optical beam propagating through the waveguide 110 can be adiabatically coupled with the silicon channel 112.

The first contact 130 is doped with the first dopant and is disposed over and around the waveguide 110. The first contact 130 includes a first contact lead 131 that is disposed in contact with an uppermost surface 1220 of the upper portion 122.

The second contact 140 is doped with the second dopant and includes a first lead 141 and a second lead 142. The first lead 141 extends through a first side 1101 of the waveguide 110 and terminates at a corresponding first side 1231 of the lower portion 123. The first lead 141 includes a first horizontal section 1411 that extends horizontally through the first side 1101 of the waveguide 110 and a first vertical section 1412 that extends vertically from an end of the first horizontal section 1411 to a lowermost surface 124 of the lower portion 123 at the first side 1231 of the lower portion 123. The second lead 142 extends through a second side 1102 of the waveguide 110 and terminates at a corresponding second side 1232 of the lower portion 123. The second lead 142 includes a second horizontal section 1421 that extends horizontally through the second side 1102 of the waveguide 110 and a second vertical section 1422 that extends vertically from an end of the second horizontal section 1421 to the lowermost surface 124 of the lower portion 123 at the second side 1102 of the lower portion 123.

In accordance with embodiments, the first dopant can be a p-type dopant and the second dopant can be an n-type dopant or the first dopant can be an n-type dopant and the second dopant can be a p-type dopant. That is, in the former case, the upper portion 122 and the first contact 130 can be doped with the p-type dopant and the lower portion 123 and the second contact 140 (including the first lead 141 and the second lead 142) can be doped with the n-type dopant whereas, in the latter case, the upper portion 122 and the first contact 130 can be doped with the n-type dopant and the lower portion 123 and the second contact 140 (including the first lead 141 and the second lead 142) can be doped with the p-type dopant.

With continued reference to FIG. 1 and with additional reference to FIG. 2, with the configuration of the photonic device 101 described above, there is a reduced length of the second contact 140 as compared to conventional configurations. This leads to a reduced electrical resistance in the second contact 140 and an increased overall efficiency of the photonic device 101. In addition, as shown in FIG. 2, the configuration of the photonic device 101 of FIG. 1 also provides for increased confinement of the optical beam 201 propagating through the waveguide 110. This leads to increased optical output of the photonic device 101 when the first contact 130 and the second contact 140 are exposed to an electric field.

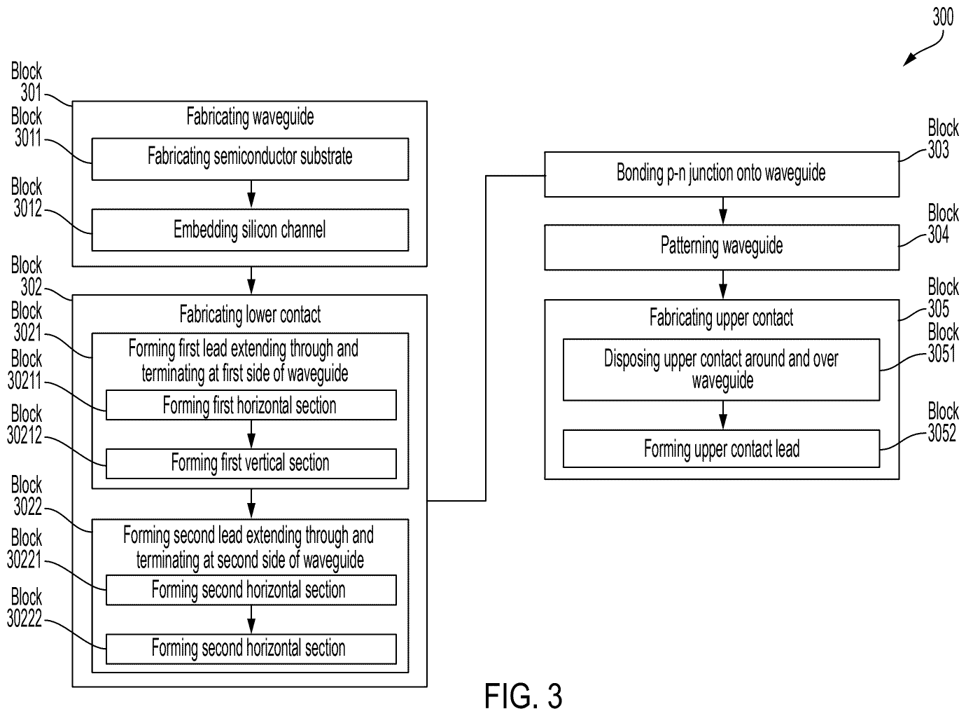

With reference to FIG. 3, a method 300 of assembling a photonic device, such as the photonic device 101 of FIG. 1, is provided. The method 300 includes fabricating a waveguide (block 301), where the waveguide can be a silicon waveguide and the fabricating of the waveguide of block 301 includes fabricating a semiconductor substrate (block 3011) and embedding a silicon channel in the semiconductor substrate (block 3012). The method 300 further includes fabricating a lower contact (block 302) where the lower contact is doped with a lower contact dopant (i.e., an n-type dopant or a p-type dopant). The fabricating of the lower contact of block 302 can include forming a first lead extending through and terminating at a first side of the waveguide (block 3021) and forming a second lead extending through and terminating at a second side of the waveguide (block 3022). The forming of the first lead of block 3021 can include forming a first horizontal section which extends horizontally through the first side of the waveguide (block 30211) and forming a first vertical section that extends vertically from an end of the first horizontal section (block 30212). The forming of the second lead of block 3022 can include forming a second horizontal section which extends horizontally through the second side of the waveguide (block 30221) and forming a second vertical section that extends vertically from an end of the second horizontal section (block 30222). The method 300 can also include bonding, onto the waveguide, a p-n junction (block 303) where the p-n junction includes a quantum well between an upper portion doped with an upper contact dopant (i.e., a p-type dopant or an n-type dopant) and a lower portion doped with the lower contact dopant (i.e., an n-type dopant or a p-type dopant). The upper portion of the p-n junction can include a III-V semiconductor and the lower portion of the p-n junction can include a III-V semiconductor. The bonding of block 303 can be executed by a chip flipping operation such that the lower portion contacts the first and second leads. In addition, the method 300 includes patterning the waveguide (block 304) and fabricating an upper contact doped with the upper contact dopant (i.e., a p-type dopant or an n-type dopant) to contact the upper portion (block 305). The fabricating of the upper contact of block 305 can include disposing the upper contact around and over the waveguide (block 3051) and forming an upper contact lead to contact an upper surface of the upper portion (block 3052).

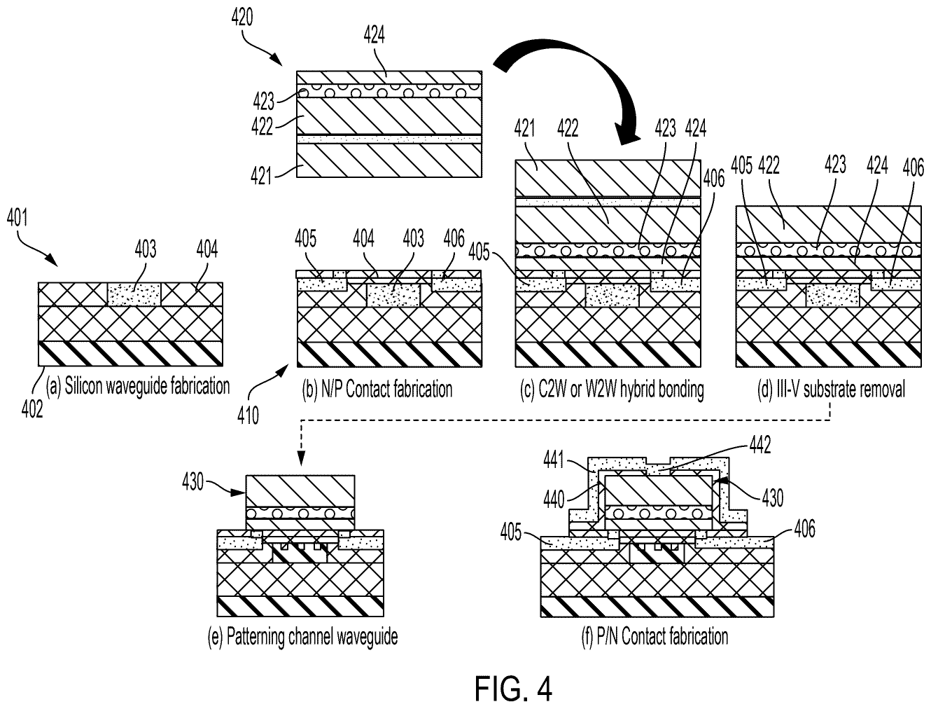

With continued reference to FIG. 3 and with additional reference to FIG. 4, an illustration of the method 300 is provided. As shown in image (a) of FIG. 4, silicon waveguide formation results in an initial semiconductor substrate structure 401 with a silicon base 402 and a silicon channel 403 partially embedded in semiconductor material 404. The silicon channel 403 can be planarized or patterned as shown in the images (e) and (f) of FIG. 4. As shown in image (b) of FIG. 4, the first and second leads 405 and 406 of the lower contact are formed on either side of the silicon waveguide with horizontal sections and vertical sections and additional semiconductor material 404 is provided to completely embed the silicon channel 403. This results in the formation of a semiconductor substrate 410. As shown in the image (c) of FIG. 4, a p-n junction structure 420 is formed and includes a handle portion 421, an upper portion 422, a quantum well 423, a lower portion 424 and optionally a semiconductor substrate layer (not shown) with portions of vertical sections of the first and second leads. As further shown in the image (c) of FIG. 4, the p-n junction structure 420 is flipped over and hybrid bonded to an uppermost surface of the semiconductor substrate 401 which brings the lower portion 424 into electrical contact with the first and second leads 405 and 406 of the lower contact. As shown in the image (d) of FIG. 4, the handle portion 421 of the p-n junction structure 420 is removed. As shown in the image (e) of FIG. 4, the p-n junction structure 420 is patterned into a p-n junction 430. As shown in the image (f) of FIG. 4, semiconductor material 440 is disposed over and around the first and second leads 405 and 406 of the lower contact and the p-n junction 430 and the upper contact 441 is formed and disposed over and around the semiconductor material 440 with an upper contact lead 442 disposed in electrical contact with the upper portion 422.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A photonic device, comprising:
a waveguide;
a p-n junction disposed on the waveguide and comprising a quantum well between an upper portion doped with a first dopant and a lower portion doped with a second dopant;
a first contact doped with the first dopant disposed in contact with the upper portion; and
a second contact doped with the second dopant and comprising:
a first lead which extends through a first side of the waveguide and terminates at a corresponding first side of the lower portion; and
a second lead which extends through a second side of the waveguide and terminates at a corresponding second side of the lower portion.

2. The photonic device according to claim 1, wherein the waveguide is a silicon waveguide.

3. The photonic device according to claim 2, wherein the silicon waveguide comprises:
a semiconductor substrate; and
a silicon channel embedded in the semiconductor substrate.

4. The photonic device according to claim 1, wherein the upper portion comprises a III-V semiconductor and the lower portion comprises a III-V semiconductor.

5. The photonic device according to claim 1, wherein the first contact is disposed around and over waveguide and comprises a first contact lead contacting an upper surface of the upper portion.

6. The photonic device according to claim 1, wherein:
the first lead comprises a first horizontal section that extends horizontally through the first side of the waveguide and a first vertical section that extends vertically from an end of the first horizontal section to a lowermost surface of the lower portion at the first side of the lower portion, and
the second lead comprises a second horizontal section that extends horizontally through the second side of the waveguide and a second vertical section that extends vertically from an end of the second horizontal section to the lowermost surface of the lower portion at the second side of the lower portion.

7. The photonic device according to claim 1, wherein the first dopant is a p-type dopant and the second dopant is an n-type dopant.

8. The photonic device according to claim 1, wherein the first dopant is an n-type dopant and the second dopant is a p-type dopant.

9. A silicon photonic device, comprising:
a semiconductor substrate;
a silicon channel embedded in the semiconductor substrate;
a p-n junction disposed on the semiconductor substrate and comprising a quantum well between an upper portion doped with a first dopant and a lower portion doped with a second dopant;
a first contact doped with the first dopant disposed in contact with the upper portion; and
a second contact doped with the second dopant and comprising:
a first lead which extends through a first side of the semiconductor substrate and terminates at a corresponding first side of the lower portion; and
a second lead which extends through a second side of the semiconductor substrate and terminates at a corresponding second side of the lower portion.

10. The silicon photonic device according to claim 9, wherein the upper portion comprises a III-V semiconductor and the lower portion comprises a III-V semiconductor.

11. The silicon photonic device according to claim 9, wherein:
the first contact is disposed around and over the semiconductor substrate and comprises a first contact lead contacting an upper surface of the upper portion,
the first lead comprises a first horizontal section that extends horizontally through the first side of the semiconductor substrate and a first vertical section that extends vertically from an end of the first horizontal section to a lowermost surface of the lower portion at the first side of the lower portion, and
the second lead comprises a second horizontal section that extends horizontally through the second side of the semiconductor substrate and a second vertical section that extends vertically from an end of the second horizontal section to the lowermost surface of the lower portion at the second side of the lower portion.

12. The silicon photonic device according to claim 9, wherein the first dopant is a p-type dopant and the second dopant is an n-type dopant.

13. The silicon photonic device according to claim 9, wherein the first dopant is an n-type dopant and the second dopant is a p-type dopant.

14. A method of assembling a photonic device, the method comprising:
fabricating a waveguide;
fabricating a lower contact doped with a lower contact dopant, the fabricating of the lower contact comprising forming a first lead extending through and terminating at a first side of the waveguide and forming a second lead extending through and terminating at a second side of the waveguide;
bonding, onto the waveguide, a p-n junction comprising a quantum well between an upper portion doped with an upper contact dopant and a lower portion doped with the lower contact dopant, the bonding being executed such that the lower portion contacts the first and second leads;
patterning the waveguide; and
fabricating an upper contact doped with the upper contact dopant to contact the upper portion.

15. The method according to claim 14, wherein the waveguide comprises a silicon waveguide and the fabricating of the waveguide comprises:
fabricating a semiconductor substrate; and
embedding a silicon channel in the semiconductor substrate.

16. The method according to claim 14, wherein:
the forming of the first lead comprises forming a first horizontal section that extends horizontally through the first side of the waveguide and forming a first vertical section that extends vertically from an end of the first horizontal section, and
the forming of the second lead comprises forming a second horizontal section that extends horizontally through the second side of the waveguide and forming a second vertical section that extends vertically from an end of the second horizontal section.

17. The method according to claim 14, wherein the upper portion comprises a III-V semiconductor and the lower portion comprises a III-V semiconductor.

18. The method according to claim 14, wherein the fabricating of the upper contact comprises:
disposing the upper contact around and over the waveguide; and
forming an upper contact lead to contact an upper surface of the upper portion.

19. The method according to claim 14, wherein the lower contact dopant is an n-type dopant and the upper contact dopant is a p-type dopant.

20. The method according to claim 14, wherein the lower contact dopant is a p-type dopant and the upper contact dopant is an n-type dopant.
